(19) United States
(12) Patent Application Publication
(10) Pub. No.: US 2024/0316897 A1
(43) Pub. Date: Sep. 26, 2024

(54) INTEGRATED MOLDED BODY AND ELECTRONIC DEVICE HOUSING

(71) Applicant: Toray Industries, Inc., Tokyo (JP)

(72) Inventors: Keisuke Shiozaki, Nagoya-shi, Aichi (JP); Kenya Okada, Nagoya-shi, Aichi (JP); Tatsuya Abe, Nagoya-shi, Aichi (JP)

(73) Assignee: Toray Industries, Inc., Tokyo (JP)

(21) Appl. No.: 18/580,341

(22) PCT Filed: Jul. 20, 2022
(86) PCT No.: PCT/JP2022/028165

§ 371 Date: Jan. 18, 2024

(30) Foreign Application Priority Data
Jul. 29, 2021 (JP) 2021-123873

(51) Int. Cl. B32B 5/24; B32B 5/02; B32B 5/18; B32B 5/26; B32B 7/027; B32B 27/12; B32B 27/32; H05K 5/02

(52) U.S. Cl. CPC B32B 5/245; B32B 5/02; B32B 5/18; B32B 5/26; B32B 7/027; B32B 27/12; B32B 27/32; B32B 2250/05; B32B 2250/40; B32B 2260/023; B32B 2260/046; B32B 2262/106; B32B 2266/025; B32B 2307/302; B32B 2307/72; B32B 2457/00; H05K 5/0217

(57) ABSTRACT

A thermally conductive, light, and rigid integrally molded body includes a laminate that is excellent in thermal conductivity, lightness, and rigidity and integrated with one or more other members is provided. An integrally molded body includes a laminate including at least prepregs that are laminated and made of a continuous carbon fiber and a resin, and a structure made of a thermoplastic resin and a reinforcing fiber and disposed on a periphery of the laminate, in which the prepregs include a first prepreg constituting the outermost layer of the laminate and including a continuous carbon fiber having a thermal conductivity λ1A of 100 (W/(m·K)) or more and 800 (W/(m·K)) or less in a fiber direction. The integrally molded body is preferably used for an electronic device housing.

### TECHNICAL FIELD

This disclosure relates to an integrally molded body and an electronic device housing that are excellent in lightness, rigidity, and thermal conductivity, and that include a laminate including a continuous carbon fiber of a specific thermal conductivity and excellent in lightness, thinness, and rigidity.

### BACKGROUND

There has been a growing demand for better portability and higher performance of electric or electronic devices such as personal computers, OA devices, AV devices, mobile phones, telephones, facsimiles, home electric appliances, and toy products. To meet such a demand, components, in particular a housing, constituting the devices are required to have a heat dissipation property so that heat generated from internal components can be efficiently released to the outside of a product and the internal components can be protected against heat from the outside, in addition to being light and miniaturized.

International Publication No. 2016/002457 discloses a configuration in which a material having high thermal conductivity such as metal is laminated inside a sandwich structure to enhance a heat dissipation property. Japanese Patent No. 4973364 discloses a configuration in which a material having high thermal conductivity is included in a laminate plate.

Japanese Patent No. 4973364 provides a thermally conductive molded body including: a first member made of a resin composition reinforced with a continuous reinforcing fiber group; and a second member, the first member and the second member being integrated. The first member and the second member are firmly integrated to be excellent in bonding strength while securing lightness and mechanical properties, and maintaining characteristics as a thermally conductive molded body by a high thermal conductivity of both the reinforcing fibers included in the first member and the second member. Japanese Patent No. 4973364 also discloses a bonding method capable of achieving both moldability of a complicated shape and productivity in such a thermally conductive molded body.

However, in International Publication No. 2016/002457, the necessity of laminating and integrating the substrates of different materials makes it difficult to manage adhesiveness and warpage of each layer and causes a problem in moldability. In addition, in Japanese Patent No. 4973364, since the integrally molded body itself has a high thermal conductivity, there is a problem of similarly transferring heat from the outside to the inside of a product for use in an electronic device.

It could therefore be helpful to provide a laminate excellent in thermal conductivity, lightness, and rigidity as compared with such conventional techniques, as well as an integrally molded body and an electronic device housing that include the laminate and one or more other members integrated with the laminate and that are excellent in thermal conductivity, lightness, and rigidity.

### SUMMARY

We thus provide:
(1) An integrally molded body including a laminate and a structure, the laminate including at least prepregs that are laminated and made of a continuous carbon fiber and a resin, the structure being made of a thermoplastic resin and a reinforcing fiber and disposed on a periphery of the laminate, in which the prepregs include a first prepreg constituting an outermost layer of the laminate and including a continuous carbon fiber having a thermal conductivity λ1A of 100 (W/(m·K)) or more and 800 (W/(m·K)) or less in a fiber direction.
(2) The integrally molded body according to (1), in which the laminate includes a core layer and the prepregs and has a sandwich structure with the prepregs being disposed on both sides of the core layer.
(3) The integrally molded body according to (2), in which the core layer is a foamed molded body made of a foamed resin, or a porous substrate made of a discontinuous fiber and a thermoplastic resin.
(4) The integrally molded body according to any one of items (1) to (3) satisfying (i) and/or (ii) below:
   (i) the laminate includes a core layer and the prepregs and has a sandwich structure with the prepregs being disposed on both sides of the core layer, and satisfies (i-1) or (i-2) below,
   (i-1) the core layer is a foamed molded body made of a foamed resin, the foamed molded body having a thermal conductivity λ21, in which a ratio λ21/λ1A of the thermal conductivity λ21 to the thermal conductivity λ1A is more than 0 and 0.05 or less,
   (i-2) the core layer is a porous substrate including a discontinuous fiber and a thermoplastic resin, the discontinuous fiber included in the porous substrate being a carbon fiber and having a thermal conductivity λ22 in a fiber direction, in which a ratio λ22/λ1A of the thermal conductivity λ22 to the thermal conductivity λ1A is more than 0 and 1.0 or less;
   (ii) the prepregs included in the laminate includes a dissimilar carbon fiber prepreg that is a prepreg other than the first prepreg 21 and includes a continuous carbon fiber that is different in type from the continuous carbon fiber included in the first prepreg 21, in which a ratio λ1B/λ1A of a thermal conductivity λ1B of a carbon fiber having a lowest thermal conductivity in the dissimilar carbon fiber prepregs to the thermal conductivity λ1A is more than 0 and 1.0 or less.
(5) The integrally molded body according to any one of (1) to (4), in which a density of the continuous carbon fiber included in the first prepreg is 2.0 g/cm³ to 2.5 g/cm³.
(6) The integrally molded body according to any one of (1) to (5), in which a continuous fiber woven-fabric substrate is disposed on a further outer side of at least one of outermost layers of the laminate to form a design surface.
(7) The integrally molded body according to any one of (1) to (6), in which a thermoplastic resin substrate is at least partially disposed between the laminate and the structure.
(8) The integrally molded body according to any one of (1) to (7) that is used as an electronic device housing.
(9) An electronic device housing including the integrally molded body according to any one of (1) to (8).

We thus provide an integrally molded body and an electronic device housing that include a laminate excellent in thermal conductivity, lightness and rigidity and one or more other members integrated with the laminate and that are excellent in thermal conductivity, lightness, and rigidity can be obtained. It is further possible to suppress heat conduction from the outside or the inside to the opposite surface and diffuse the heat in the in-plane direction, and in use for an electronic device housing, as well as to prevent the influence of heat from the outside, and a local high temperature on a design surface due to internal heat generation. Such an integrally molded body and an electronic device housing can be obtained.

### BRIEF DESCRIPTION OF THE DRAWINGS

FIG. 1 is a schematic perspective view of an integrally molded body 10 according to an example.

FIG. 2 is a schematic cross-sectional view in the thickness direction of the integrally molded body 10 including a laminate 20 including a first prepreg 21 and a second prepreg, and a resin member bonded to a periphery of the laminate 20 as viewed along line A-A′ in FIG. 1.

FIG. 3 is a schematic cross-sectional view in the thickness direction of the integrally molded body 10 including a core layer including a foamed molded body 40, and a resin member bonded to a peripheral portion of the laminate 20.

FIG. 4 is a schematic cross-sectional view in the thickness direction of the integrally molded body 10 including the laminate 20 including the first prepreg 21 and the second prepreg, and a continuous fiber woven-fabric substrate disposed on the further outer side of the laminate 20 to form a design surface.

FIG. 5 is a schematic cross-sectional view in the thickness direction of the integrally molded body 10 including the laminate 20 including a thermoplastic resin layer, and a resin member bonded to a peripheral portion of the laminate 20.

FIG. 6 is a schematic cross-sectional view in the thickness direction of the integrally molded body 10 including the laminate 20 that includes a core layer including a porous substrate 50 and has a thickness difference, and a resin member bonded to a peripheral portion of the laminate 20.

FIG. 7 is a schematic cross-sectional view in the thickness direction of the integrally molded body 10 in which a resin member is bonded to a peripheral portion using a resin frame 80.

### DESCRIPTION OF REFERENCE SIGNS

10: Integrally molded body
20: Laminate
21: First prepreg
21a: Prepreg region as first flat portion
21b: Prepreg region as inclined portion
21c: Prepreg region as second flat portion
22: Second prepreg
30: Structure
31: Bonding surface with laminate
32: Length in thickness direction at bonding portion with laminate
40: Foamed molded body
50: Porous substrate
50a: Porous substrate region as first flat portion
50b: Porous substrate region as inclined portion
50c: Porous substrate region as second flat portion
60: Continuous fiber woven-fabric substrate
70: Thermoplastic resin substrate
80: Resin frame

### DETAILED DESCRIPTION

Hereinafter, examples will be described with reference to the drawings. Our molded bodies and housing are not limited to the drawings or the examples.

An integrally molded body 10 includes a laminate 20 including at least prepregs that are laminated and made of a continuous carbon fiber and a resin, and a structure 30 made of a thermoplastic resin and a reinforcing fiber and disposed on the periphery of the laminate 20. The prepregs include a first prepreg 21 constituting the outermost layer of the laminate 20 and including a continuous carbon fiber having a thermal conductivity λ1A of 100 (W/(m·K)) or more and 800 (W/(m·K)) or less in a fiber direction. The “laminate 20 including at least prepregs that are laminated” means a laminate including a prepreg as a lamination unit, and lamination units other than prepregs may be included. The prepregs may contain other components in addition to the continuous carbon fiber and the resin. The resin described here is a matrix resin and may be a single resin or may be a resin composition. Similarly, the structure 30 may contain other components in addition to the thermoplastic resin and the reinforcing fiber.

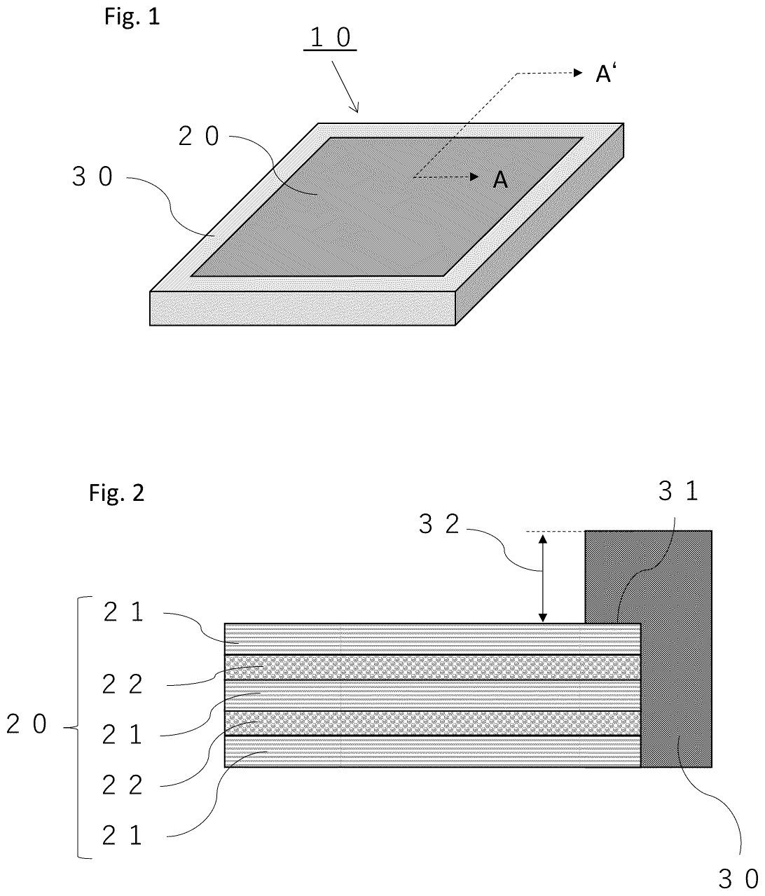

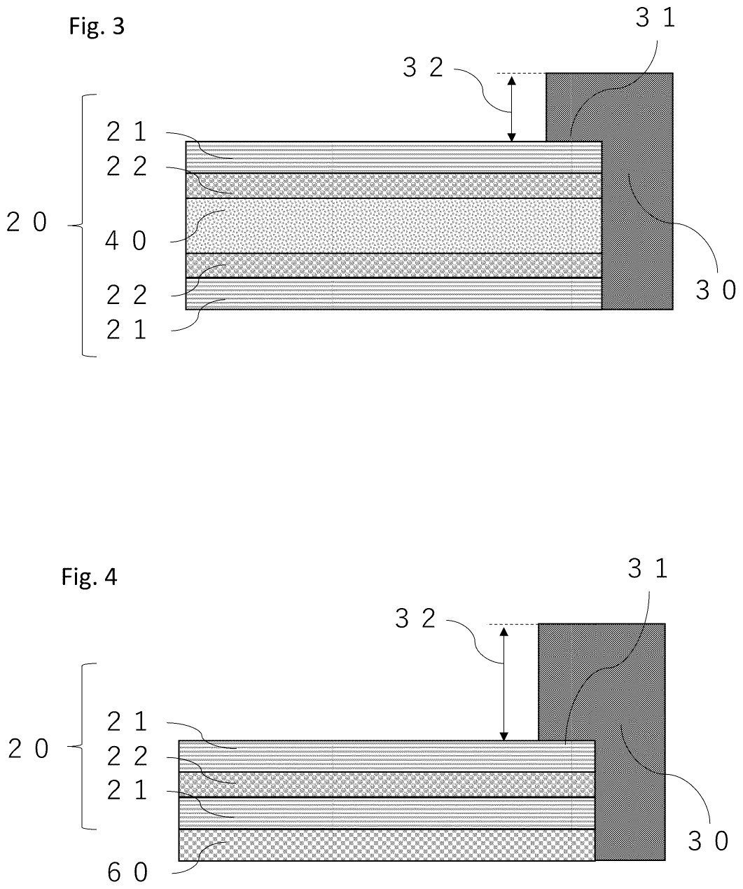

The integrally molded body 10 according to the example includes the laminate 20 and the structure 30 bonded to a peripheral portion of the laminate 20 as illustrated in FIG. 2. The configuration of the laminate 20 may be determined according to the application or the required performance of the integrally molded body 10, which may be a configuration of including a core layer in an inner layer as illustrated in FIG. 3 to be described later, and a configuration of disposing a continuous fiber woven-fabric substrate on a design surface as illustrated in FIG. 4 to be described later. FIG. 2 is a schematic cross-sectional view in the thickness direction of the integrally molded body 10 as viewed along the line A-A′ in FIG. 1, but is illustrated upside down with respect to FIG. 1. Furthermore, FIGS. 3 to 7 are similarly illustrated upside down with respect to FIG. 1.

Continuous fibers and discontinuous fibers are defined. The continuous fibers are reinforcing fibers contained in the integrally molded body 10 that are substantially continuously arranged over the entire length or the entire width of the integrally molded body 10. The discontinuous fibers are reinforcing fibers that are discontinuously divided and arranged. In general, fibers contained in a unidirectional fiber-reinforced resin in which reinforcing fibers arranged in one direction are impregnated with a resin correspond to continuous fibers. Fibers contained in, for example, a base material of a sheet molding compound (SMC) substrate used for press molding or a pellet material containing reinforcing fibers and used for injection molding correspond to discontinuous fibers. The continuous fiber refers to a reinforcing fiber continuous at least over a length of 100 mm or more in one direction.

For the continuous carbon fibers, carbon fibers (including graphite fibers) excellent in specific strength and specific rigidity such as polyacrylonitrile (PAN)-based carbon fibers, rayon-based carbon fibers, lignin-based carbon fibers, and pitch-based carbon fibers are preferably used from the viewpoint of the weight reduction effect. Among them, it is preferred to use a pitch-based carbon fiber excellent in thermal conductivity for at least one or more layer of the laminate 20, and it is also preferred to use a polyacrylonitrile (PAN)-based carbon fiber in combination from the viewpoint of costs.

From the viewpoint of the heat dissipation property of the integrally molded body 10, it is important that the thermal conductivity λ1A of the continuous carbon fiber included in the first prepreg 21 constituting the outermost layer of the laminate 20 in the fiber direction is 100 W/(m·K) or more and 800 (W/(m·K)) or less. If the thermal conductivity λ1A is less than 100 W/(m·K), the generated heat cannot be dissipated, and the heat is accumulated inside a product, which may damage the inside. The thermal conductivity λ1A is preferably 150 W/(m·K) or more and 800 W/(m·K) or less, and more preferably 300 W/(m K) or more and 800 W/(m·K) or less from the viewpoint of a balance between productivity and thermal conductivity. The thermal conductivity of the carbon fiber in the fiber direction can be measured by a test described in JIS A1412-2 (1999).

Using such a continuous carbon fiber makes it possible to obtain a laminate excellent in thermal conductivity, lightness, and rigidity.

Continuous carbon fibers having a tensile modulus preferably 200 to 1000 GPa can be used from the viewpoint of the rigidity of the laminate 20, and more preferably, continuous carbon fibers having a tensile modulus 280 to 900 GPa can be used from the viewpoint of the handleability of the prepregs. When the tensile modulus of the carbon fiber is less than 200 GPa, the rigidity of a sandwich structure may be poor, and when the tensile modulus of the carbon fiber is more than 1000 GPa, the crystallinity of the carbon fiber needs to be enhanced, which makes it difficult to produce carbon fibers. It is preferred that the tensile modulus of the carbon fiber is within the above range from the viewpoint of further improving the rigidity of the sandwich structure and improving the productivity of carbon fibers. The tensile modulus of the carbon fiber can be measured by a strand tensile test described in JIS R7301 (1986).

In particular, the tensile modulus of the continuous carbon fiber included in the prepreg constituting the outermost layer is preferably 400 to 1000 GPa from the viewpoint of the rigidity of the laminate 20, and more preferably, 500 to 900 GPa.

The density of the carbon fiber used for the continuous carbon fiber is preferably, when polyacrylonitrile (PAN)-based carbon fiber, 1.6 g/cm³ or more and 2.0 g/cm³ or less, and from the viewpoint of improving rigidity, 1.8 g/cm³ or more and 2.0 g/cm³ or less, and when pitch-based carbon fiber, 2.0 g/cm³ or more and 2.5 g/cm³ or less, and from the viewpoint of costs, 2.0 g/cm³ or more and 2.3 g/cm³ or less.

The density of the continuous carbon fiber included in the first prepreg 21 constituting the outermost layer of the laminate 20 is preferably 2.0 g/cm³ to 2.5 g/cm³. Furthermore, the density is more preferably 2.0 g/cm³ or more and 2.3 g/cm³ or less from the viewpoint of costs. The density of the carbon fiber can be measured by a test described in JIS R7603-A (1999).

The resin included in the prepregs is not limited to a particular resin, and a thermoplastic resin or a thermosetting resin can be used. When thermoplastic resin, for example, the same type of resin as that of the thermoplastic resin included in the core layer described later can be used. As the thermosetting resin, thermosetting resins such as unsaturated polyester resin, vinyl ester resin, epoxy resin, phenol (resol type) resin, urea melamine resin, polyimide resin, maleimide resin, and benzoxazine resin can be preferably used. Two or more of these resins may be blended and used. Among them, an epoxy resin is particularly preferable from the viewpoint of mechanical properties and heat resistance of the molded body. It is preferred that the epoxy resin is contained as a main component of the resin to be used in terms of its excellence in mechanical properties to be exhibited. Specifically, when the epoxy resin is included with other components to form a resin composition, it is preferred that the epoxy resin is contained in an amount of 30% by mass or more of the resin composition.

The fiber weight content of the continuous carbon fiber included in the prepregs is preferably 30 to 70% by mass from the viewpoint of moldability and buckling characteristics of the laminate 20. When the content is less than 30% by mass, it may be difficult to achieve the buckling strength of the laminate 20. When the content is more than 70% by mass, the resin may be insufficient, thereby impairing the design after molding. The content is preferably 62 to 68% by mass.

The thickness of the prepreg is preferably 0.05 to 1.00 mm from the viewpoint of the thickness of the laminate 20. From the viewpoint of design flexibility, the thickness is more preferably 0.05 to 0.20 mm. When the thickness of the prepreg is less than 0.05 mm, handling may become difficult.

From the viewpoint of reducing weight and increasing rigidity of the laminate 20, it is preferred that the laminate 20 has a sandwich structure with the prepregs being disposed on both sides of a core layer as illustrated in FIG. 3.

Including such a core layer makes it possible to obtain a lighter and more rigid laminate.

As the core layer, it is preferred to use a foamed molded body 40 or a porous substrate 50. It is preferred that the foamed molded body 40 is made of a foam resin, and the porous substrate 50 is a substrate made of a discontinuous fiber and a thermoplastic resin.

As the type of resin when using the foamed molded body 40 for the core layer, the thermosetting resins and the thermoplastic resins described above can be used. Among them, polyurethane resin, phenol resin, melamine resin, acrylic resin, polyethylene resin, polypropylene resin, polyvinyl chloride resin, polystyrene resin, acrylonitrile-butadiene-styrene (ABS) resin, polyetherimide resin, or polymethacrylimide resin can be suitably used. Specifically, to ensure lightness, it is preferred to use a resin having an apparent density smaller than that of the prepregs. In particular, polyurethane resin, acrylic resin, polyethylene resin, polypropylene resin, polyetherimide resin, or polymethacrylimide resin can be preferably used. The exemplified resins may contain an impact resistance improver such as elastomer or a rubber component, another filler, or additive as long as the desired object is not impaired. Examples thereof include inorganic fillers, flame retardants, conductivity imparting agents, crystal nucleating agents, ultraviolet absorbers, antioxidants, vibration suppressing agents, antibacterial agents, insect repellents, deodorants, coloring inhibitors, heat stabilizers, release agents, antistatic agents, plasticizers, lubricants, colorants, pigments, dyes, foaming agents, defoaming agents, and coupling agents.

When the value of the ratio λ21/λ1A of the thermal conductivity of the foamed molded body 40 used for the core layer to the thermal conductivity of the prepregs increases, the thermal conduction in the thickness direction increases and the thermal conduction in the in-plane direction decreases. A smaller value of λ21/λ1A increases heat conduction in the in-plane direction, and this reduces the influence of local heating when the integrally molded body is used for an electronic device housing. In this regard, the value of −λ1/λ1A is preferably more than 0 and 0.05 or less from the viewpoint of lightness, heat dissipation property and rigidity, and more preferably more than 0 and less than 0.01 from the viewpoint of heat dissipation property.

The value of the thermal conductivity λ21 (W/(m·K)) of the foamed molded body 40 used for the core layer is preferably more than 0 W/(m·K) and 10 W/(m·K) or less. When the thermal conductivity λ21 exceeds 10 W/(m·K), the generated heat is transferred to the inside/outside, which may affect internal components or may cause burning during use. The thermal conductivity λ21 is preferably more than 0 W/(m·K) and 5 W/(m·K) or less, and more preferably more than 0 W/(m·K) and 1 W/(m·K) or less. The thermal conductivity of the foamed molded body 40 can be measured by a test described in JIS H7903 (2008).

As the porous substrate 50 used for the core layer, it is preferred to use a precursor including a discontinuous fiber and a thermoplastic resin and heated and expanded in the thickness direction by spring back to form voids. A molded body containing the discontinuous fiber and the thermoplastic resin included in the core layer is heated and pressurized to a softening point or melting point of the resin or higher, and then pressurization is released, and the molded body is expanded by a restoring force of returning to the original state, which is what is called spring back, upon releasing of the residual stress of the discontinuous fiber, whereby desired voids can be formed in the core layer. In the restoration process, suppressing the restoration behavior in a certain region by a certain pressurization means or the like can keep porosity at a low level.

As the carbon fibers used for the core layer, carbon fibers (including graphite fibers) such as polyacrylonitrile (PAN)-based carbon fibers, rayon-based carbon fibers, lignin-based carbon fibers, and pitch-based carbon fibers are preferably used. Among them, it is preferred to use polyacrylonitrile (PAN)-based carbon fibers excellent in productivity.

The value of the ratio λ22/λ1A of the thermal conductivity of the porous substrate 50 used for the core layer to the thermal conductivity of the prepregs is preferably more than 0 and 1.0 or less for the same reason as the above-described ratio λ21/λ1A of the thermal conductivity of the foamed molded body 40 to the thermal conductivity of the prepregs, and is more preferably more than 0 and less than 0.5 from the viewpoint of lightness and rigidity, and still more preferably more than 0 and less than 0.1 from the viewpoint of heat dissipation property.

The value of the thermal conductivity λ22 (W/(m·K)) of the carbon fiber used for the core layer in the fiber direction is preferably 50 W/(m·K) or less. When the thermal conductivity λ22 exceeds 50 W/(m·K), the generated heat is transferred to the inside/outside, which may affect internal components or may cause burning during use. The thermal conductivity λ22 is preferably 0.1 W/(m·K) or more and 10 W/(m·K) or less, and more preferably 3 W/(m· K) or more and 8 W/(m·K) or less. The thermal conductivity of the carbon fiber in the fiber direction can be measured by a test described in JIS A1412-2 (1999).

The fiber weight content of the discontinuous fiber included in the core layer is preferably 5 to 75% by mass, and the weight content of the thermoplastic resin therein is preferably 25 to 95% by mass.

In the formation of the core layer, the proportion of the blending amount of the discontinuous fiber to the thermoplastic resin is one element for specifying the porosity. The method of obtaining the proportion of the blending amount of the discontinuous fiber to the thermoplastic resin is not limited to a particular method and, for example, the proportion of the blending amount can be obtained by removing the resin component contained in the core layer and measuring the weight of only the remaining discontinuous fibers. Examples of the method of removing the resin component contained in the core layer include a dissolution method and a burning method. The weight can be measured using an electronic scale or an electronic balance. The size of the molding material to be measured is 100 mm by 100 mm square, and the number of measurements is n=3 and the average value thereof can be used.

The proportion of the blending amount of the discontinuous fiber in the core layer is preferably 7 to 70% by mass and that of the thermoplastic resin is preferably 30 to 93% by mass, and more preferably 20 to 50% by mass of the discontinuous fiber and 50 to 80% by mass of the thermoplastic resin, and still more preferably 25 to 40% by mass of the discontinuous fiber and 60 to 75% by mass of the thermoplastic resin. When the content of the discontinuous fiber is less than 5% by mass and that of the thermoplastic resin is more than 95% by mass, spring back is less likely to occur and the porosity cannot be increased. This configuration may fail to provide regions having different porosities in the core layer and the bonding strength with the structure is reduced. When the content of the discontinuous fiber is more than 75% by mass and that of the thermoplastic resin is less than 25% by mass, the specific rigidity of the laminate 20 decreases.

The number average fiber length of the discontinuous fiber included in the core layer is preferably 0.5 to 50 mm. Setting the number average fiber length of the discontinuous fiber to a specific length can ensure generation of voids by spring back in the core layer. The number average fiber length is preferably 0.8 to 40 mm, more preferably 1.5 to 20 mm, and still more preferably 3 to 10 mm. When the number average fiber length is shorter than 0.5 mm, it may be difficult to form voids having a certain size or more. When the number average fiber length is longer than 50 mm, it is difficult to randomly disperse the fibers from the fiber bundle, and the core layer cannot generate sufficient spring back, thereby limiting the size of voids and reducing the bonding strength with the structure.

As a method of measuring the fiber length of the discontinuous fiber, for example, there is a method of directly extracting discontinuous fibers from a discontinuous fiber group and measuring the fiber length by microscopic observation. When resin is attached to the discontinuous fiber group, for example, the resin is dissolved from the discontinuous fiber group in a solvent that dissolves only the resin contained in the discontinuous fiber group, and the remaining discontinuous fibers are separated by filtration and measured by microscopic observation (dissolution method). When there is no solvent that dissolves the resin, for example, only the resin is burned off in a temperature range in which the discontinuous fibers are not oxidized and reduced, to thereby separate the discontinuous fibers, and the separated fibers are measured by microscopic observation (burning-off method). Four hundred discontinuous fibers are randomly selected from the discontinuous fiber group, and the lengths thereof are measured in the order of 1 μm with an optical microscope, and then the fiber length and the proportion thereof can be obtained. When the method of directly extracting discontinuous fibers from a discontinuous fiber group is compared with the method of extracting the discontinuous fibers by the burning-off method or the dissolution method, no special difference is produced in the obtained result as long as the conditions are properly selected. Among these measurement methods, it is preferred to use the dissolution method in terms of a smaller weight change of the discontinuous fibers.

A mat of discontinuous fibers suitably used for a core layer having voids or a molded body in which discontinuous fibers are impregnated with a thermoplastic resin is produced such that, for example, discontinuous fibers are previously dispersed in a fiber bundle shape and/or a monofilament shape. Specifically, as a method of manufacturing the discontinuous fiber mat, dry processes such as an airlaid method in which discontinuous fibers are dispersed with an air flow and formed into a sheet and a carding method in which discontinuous fibers are formed by mechanical combing and made into a sheet, and a wet process by the Radright method in which discontinuous fibers are stirred in water and made into paper can be used.

Examples of means of bringing the discontinuous fibers closer to a monofilament shape include, in the dry process, a method of providing spreader bars, a method of vibrating the spreader bars, a method of providing fine (extra-fine) carding pins, and a method of adjusting the rotation speed of the carding machine, and in the wet process, a method of adjusting the stirring condition of the discontinuous fibers, a method of diluting the reinforcing fiber concentration in dispersion, a method of adjusting the viscosity of the dispersion, and a method of suppressing a vortex flow when transferring the dispersion.

In particular, the discontinuous fiber mat is preferably manufactured by a wet process, and the proportion of the reinforcing fibers in the discontinuous fiber mat can be easily adjusted by increasing the concentration of input fibers or adjusting the flow speed (flow rate) of the dispersion and the speed of the mesh conveyor. For example, decreasing the speed of the mesh conveyor with respect to the flow speed of the dispersion makes the orientation of the fibers in the obtained mat made of discontinuous fibers less likely to be directed toward the pulling direction, and thus a bulky mat made of discontinuous fibers can be manufactured. The mat made of discontinuous fibers may include discontinuous fibers only, may include a mixture of discontinuous fibers with a matrix resin component having a powder or fiber form, may include a mixture of discontinuous fibers with an organic or inorganic compound, or may include discontinuous reinforcing fibers that are bonded to each other with a resin component.

The type of the thermoplastic resin used for the core layer is not limited to a particular type, and any of the thermoplastic resins described below can be used. Examples of the thermoplastic resin include polyester resins such as a polyethylene terephthalate (PET) resin, a polybutylene terephthalate (PBT) resin, a polytrimethylene terephthalate (PTT) resin, a polyethylene naphthalate (PEN) resin, and a liquid crystal polyester resin: polyolefin resins such as polyethylene (PE) resin, polypropylene (PP) resin, and a polybutylene resin: polyarylene sulfide resins such as a polyoxymethylene (POM) resin, a polyamide (PA) resin, and a polyphenylene sulfide (PPS) resin; fluorine-based resins such as a polyketone (PK) resin, a polyether ketone (PEK) resin, a polyether ether ketone (PEEK) resin, a polyether ketone ketone (PEKK) resin, a polyether nitrile (PEN) resin, and a polytetrafluoroethylene resin: crystalline resins such as a liquid crystal polymer (LCP): amorphous resins such as a styrene-based resin, a polycarbonate (PC) resin, a polymethyl methacrylate (PMMA) resin, a polyvinyl chloride (PVC) resin, a polyphenylene ether (PPE) resin, a polyimide (PI) resin, a polyamideimide (PAI) resin, a polyetherimide (PEI) resin, a polysulfone (PSU) resin, a polyethersulfone resin, and a polyarylate (PAR) resin: phenol-based resins: phenoxy resins: thermoplastic elastomers such as a polystyrene-based resin, a polyolefin-based resin, a polyurethane-based resin, a polyester-based elastomer resin, a polyamide-based elastomer resin, a polybutadiene-based resin, a polyisoprene-based resin, a fluorine-based elastomer resin, and an acrylonitrile-based elastomer resin, and thermoplastic resins selected from copolymers and modified products thereof. Among them, polyolefin resin is preferably used from the viewpoint of lightness of the molded article to be obtained, polyamide resin is preferably used from the viewpoint of strength, amorphous resins such as polycarbonate resin, styrene-based resin, and modified polyphenylene ether-based resin are preferably used from the viewpoint of surface appearance, polyarylene sulfide resin is preferably used from the viewpoint of heat resistance, and polyetheretherketone resin is preferably used from the viewpoint of continuous use temperature.

The exemplified thermoplastic resins may contain an impact resistance improver such as elastomer or a rubber component, another filler, or additives as long as the desired object is not impaired. Examples thereof include inorganic fillers, flame retardants, conductivity imparting agents, crystal nucleating agents, ultraviolet absorbers, antioxidants, vibration suppressing agents, antibacterial agents, insect repellents, deodorants, coloring inhibitors, heat stabilizers, release agents, antistatic agents, plasticizers, lubricants, colorants, pigments, dyes, foaming agents, defoaming agents, and coupling agents.

It is preferred that the laminate 20 includes at least two or more layers of prepregs made of at least a continuous fiber and a thermoplastic resin or a thermosetting resin, and the total thickness is 0.3 mm or more and 2.0 mm or less. When the total thickness is less than 0.3 mm, rigidity of the integrally molded body 10 is insufficient, and the difference in thermal conduction in the thickness/in-plane direction will be small and a heat dissipation property may be impaired. When the total thickness exceeds 2.0 mm, lightness may be impaired. The total thickness is more preferably 0.7 mm or more and 1.5 mm or less from the viewpoint of rigidity, heat dissipation property, and lightness.

The laminate 20 including a porous substrate as the core layer may have, as illustrated in FIG. 6, a step portion including a prepreg region 21a as a first flat portion, a prepreg region 21b as an inclined portion, and a prepreg region 21c as a second flat portion in the in-plane direction within the total thickness range. It is preferred that the prepreg region 21b has an inclined surface of 10 to 90° with respect to the in-plane direction of the prepreg region 21a as the first flat portion provided in the laminate 20. Providing the step portion enables a bonding surface 31 with the laminate to be set on the prepreg region 21c as the second flat portion. In this regard, the structure can have a longer length 32 in the thickness direction at a bonding portion with the laminate 20 without changing the thickness of the structure, and bonding strength can be improved and the integrally molded body 10 can be thinner from the viewpoint of improvement in fluidity during injection molding.

It is preferred that an inclination angle θ(°) in the in-plane direction between the first flat portion and the inclined surface is 10 to 90°.

The resin used for the structure 30 is not limited to a particular resin, and the above-described thermoplastic resins or thermosetting resins can be used. Among them, a thermoplastic resin is preferable. The thermoplastic resin of the structure 30 and a thermoplastic resin substrate 70 are melted and fixed to form a bonding structure and a higher bonding strength can be achieved as the integrally molded body 10. The melted and fixed bonding structure means a bonding structure in a state in which both members are melted by heat, cooled, and fixed. In particular, a PPS resin is more preferably used from the viewpoint of heat resistance and chemical resistance, a polycarbonate resin or a styrene-based resin is more preferably used from the viewpoint of molded article appearance and dimensional stability, and a polyamide resin is more preferably used from the viewpoint of strength and impact resistance of a molded article.

Furthermore, to increase the strength and rigidity of the integrally molded body 10, it is also preferred to use a resin containing reinforcing fibers as a material of the structure 30. Examples of the reinforcing fibers that can be used include metal fibers such as aluminum fibers, brass fibers, and stainless fibers, polyacrylonitrile-based, rayon-based, lignin-based, and pitch-based carbon fibers and graphite fibers, inorganic fibers such as glass fibers, silicon carbide fibers, and silicon nitride fibers, and organic fibers such as aramid fibers, polyparaphenylene benzobisoxazole (PBO) fibers, polyphenylene sulfide fibers, polyester fibers, acrylic fibers, nylon fibers, and polyethylene fibers. These reinforcing fibers may be used alone or in combination of two or more. Among them, carbon fibers and glass fibers are preferable from the viewpoint of strength. The reinforcing fibers are more preferably glass fibers. Using glass fibers as the reinforcing fibers enables the structure 30 to have a function as a radio wave transmission member.

The resin included in the structure 30 may further contain other fillers and additives in accordance with the required characteristics as long as the desired object is not impaired. Examples thereof include inorganic fillers, flame retardants other than phosphorus-based flame retardants, conductivity imparting agents, crystal nucleating agents, ultraviolet absorbers, antioxidants, damping agents, antibacterial agents, insect repellents, deodorants, coloring inhibitors, heat stabilizers, release agents, antistatic agents, plasticizers, lubricants, coloring agents, pigments, dyes, foaming agents, antifoaming agents, and coupling agents.

The fiber weight content of the reinforcing fibers is preferably 1 to 60% by mass of discontinuous fibers. This configuration can increase bonding strength and reduce the warpage of the integrally molded body 10. When the fiber weight content is less than 1% by mass, it may be difficult to secure the strength of the integrally molded body 10, and when the fiber weight content is more than 60% by mass, filling of the structure 30 in injection molding may be partially insufficient. From the viewpoint of moldability of the structure, the fiber weight content is preferably 5 to 55% by mass, more preferably 8 to 50% by mass, and still more preferably 12 to 45% by mass.

It is preferred that the laminate 20 having the core layer has a fitting portion that allows the structure 30 to enter a part of the laminate 20 from the viewpoint of the bonding strength of the integrally molded body 10.

When the structure 30 is formed by injection molding, the structure 30 is bonded with the flat surface portion or the side surface portion of the prepreg layers of the laminate 20, and the structure 30 enters a partial region in the core layer from the side surface portion of the laminate 20 by injection molding pressure. This is because the region in the core layer is highly porous and is configured to allow the molten structure 30 to easily penetrate. Using a porous substrate including a discontinuous fiber and a thermoplastic resin for the core layer can further enhance the bonding strength by the anchoring effect that allows the structure 30 to enter the inside of the core layer.

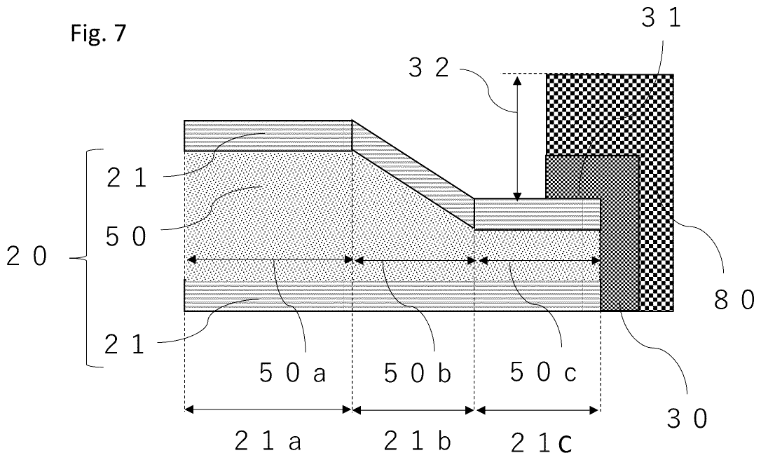

Furthermore, in the configuration of the structure 30, as illustrated in FIG. 7, disposing, as a separate member, a resin frame at a periphery of the laminate 20 before injection of a resin member and then performing injection molding of the resin member is also effective for avoiding warpage of the integrally molded body 10.

It is preferred that this resin frame 80 is a fiber-reinforced resin frame made of reinforcing fibers and a resin from the viewpoint of strength and rigidity of the integrally molded body 10. As the reinforcing fibers, reinforcing fibers used in the resin member described above can be used. Glass fibers and carbon fibers are preferably used from the viewpoint of increasing the strength of the resin frame 80. Glass fibers are preferably used as the reinforcing fibers from the viewpoint of antenna performance. When carbon fibers are used as reinforcing fibers, the antenna performance is inferior to that of glass fibers, but using carbon fibers is effective for the purpose of improving strength and rigidity.

From the viewpoint of reducing thickness and costs of the laminate 20, the prepregs included in the laminate may include a dissimilar carbon fiber prepreg that is a prepreg other than the first prepreg 21 and that includes continuous carbon fibers that are different in type from the continuous carbon fibers included in the first prepreg 21. FIG. 2 illustrates an example of the laminate 20 including the first prepreg 21 and a second prepreg 22 that is a dissimilar carbon fiber prepreg that are alternately laminated. When the prepregs are used for an electronic device housing, the value of the ratio λ1B/λ1A of the thermal conductivity λ1B of a carbon fiber having the lowest thermal conductivity in the dissimilar carbon fiber prepreg to the thermal conductivity λ1A of the first prepreg 21 is preferably more than 0 and 1.0 or less from the viewpoint of transfer of generated heat to the inside/outside and influences on the internal components or risks of burns during use. The value is more preferably more than 0 and less than 0.5 from the viewpoint of lightness and rigidity, and the value is still more preferably more than 0 and less than 0.1 from the viewpoint of heat dissipation property. The thermal conductivity λ1B of the carbon fiber having the lowest thermal conductivity is preferably 0.1 W/(m· K) or more and 10 W/(m·K) or less, and more preferably 3 W/(m· K) or more and 8 W/(m·K) or less. The thermal conductivity of the carbon fiber in the fiber direction can be measured by a test described in JIS A1412-2 (1999).

A continuous fiber woven-fabric substrate 60 may be disposed on the further outer side of at least one of the outermost layers of the laminate 20 to form a design surface. Disposing the woven-fabric pattern on the design surface side can make the design of a product more attractive. In addition, it is preferred that the number of laminated prepregs included in the laminate 20, the type of carbon fibers, and the type of resins are appropriately combined according to the characteristics and costs required for the integrally molded body 10.

The continuous fiber woven-fabric substrate 60 will be described. The continuous fiber woven-fabric substrate is a substrate in which a continuous fiber bundle in a form of thousand units of continuous fibers bundled together is used as a warp and a weft, and two sets of yarns are interlaced at a substantially right angle using a loom. In general, a continuous fiber bundle including 1000 fibers is referred to as 1K, a continuous fiber bundle including 3000 fibers is referred to as 3K, and a continuous fiber bundle including 12,000 fibers are referred to as 12K.

Examples of the fibers used for the continuous fiber woven-fabric substrate 60 include metal fibers such as aluminum fibers, brass fibers, and stainless fibers, glass fibers, polyacrylonitrile-based, rayon-based, lignin-based, or pitch-based carbon fibers and graphite fibers, organic fibers such as aromatic polyamide fibers, polyaramid fibers, PBO fibers, polyphenylene sulfide fibers, polyester fibers, acrylic fibers, nylon fibers, and polyethylene fibers, and silicon carbide fibers, silicon nitride fibers, alumina fibers, and boron fibers. These are used alone or in combination of two or more. Surface treatment may be applied to these fiber materials. Examples of the surface treatment include a metal deposition treatment, a treatment with a coupling agent, a treatment with a sizing agent, and an additive attachment treatment.

When carbon fibers are used for the continuous fiber woven-fabric substrate 60, carbon fibers (including graphite fibers) excellent in specific strength and specific rigidity such as polyacrylonitrile (PAN)-based carbon fibers, rayon-based carbon fibers, lignin-based carbon fibers and pitch-based carbon fibers are preferably used from the viewpoint of the weight reduction effect. Among them, PAN-based carbon fibers excellent in processability are desirable.

The continuous fiber woven-fabric substrate 60 is preferably at least one woven-fabric, the continuous fibers of which are selected from plain weave, twill weave and satin weave. Using the continuous fiber woven-fabric substrate 60 having characteristics in its fiber pattern can make the characteristic fiber pattern conspicuous, and disposing the continuous fiber woven-fabric substrate 60 on the further outer side of the outermost layer (design surface side) can make the shape pattern of the continuous fiber woven-fabric conspicuous and show a novel surface pattern. The continuous fiber bundle is preferably 1K to 24K, and more preferably 1K to 6K from the viewpoint of the stability of the fiber pattern during processing.

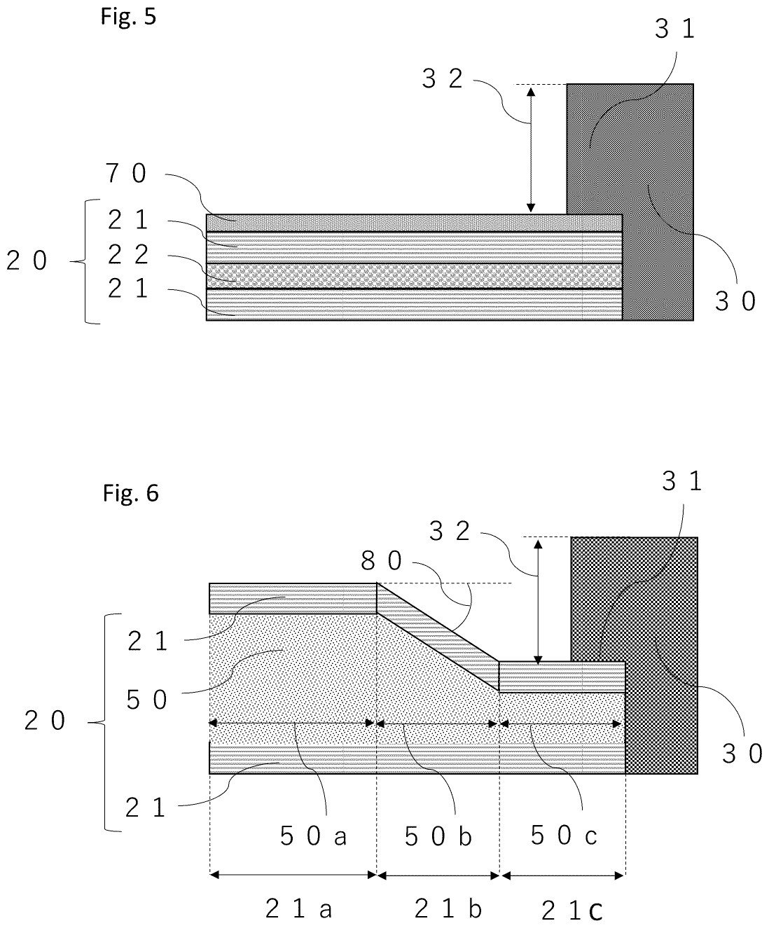

As illustrated in FIG. 5, for example, a thermoplastic resin layer can be provided by disposing the thermoplastic resin substrate 70 at least partially between the prepreg and the structure or/and between the core layer and the structure.

As the thermoplastic resin substrate 70, for example, adhesives such as an acrylic adhesive, an epoxy adhesive, a styrene adhesive, a nylon adhesive, and an ester adhesive, a thermoplastic resin film, and a nonwoven fabric can be used. Regarding the material, using the same material as that of the structure can increase the bonding strength. The resin provided on the outermost layer of the prepregs or the core layer may not necessarily be the same resin as the adhesive used for the thermoplastic resin substrate 70 and is not limited to a particular resin as long as it has good compatibility, and it is preferred to select an optimum resin according to the type of resin included in the structure.

As illustrated in the cross-sectional views of FIGS. 6 and 7, it is preferred that the laminate 20 including the porous substrate 50 has a porous substrate region 50b as the inclined portion and a porous substrate region 50c as the second flat portion that have a porosity lower than that of a porous substrate region 50a as the first flat portion from the viewpoint of rigidity and thinness of the integrally molded body 10.

### EXAMPLES

Hereinafter, the integrally molded body 10 and a method of manufacturing the same will be specifically described with reference to Examples, but the following Examples do not limit this disclosure.

### (1) Heat Dissipation Property of Integrally Molded Body 10

A micro ceramic heater (product number: MC1010) manufactured by Sakaguchi Electric Heaters Co., Ltd. was used for heat dissipation property evaluation. The integrally molded body 10 illustrated in FIG. 1 was used. A heater (not illustrated) whose temperature was raised to 40° C. and stable was placed on a center portion of the integrally molded body 10 on the design surface side to be in contact with the integrally molded body 10, and the heater was immediately turned off and was left for 10 minutes. Then, the heater was removed and a portion having the maximum surface temperature at each of the design surface side and the non-design surface side was confirmed by thermography, and the maximum temperature was measured. The maximum value of the obtained surface temperature was evaluated by A, B, and C according to the following criteria. The measurement on the design surface side was referred to as heat dissipation property X, and the measurement on the non-design surface side was referred to as heat dissipation property Y. When the heat dissipation property X and the heat dissipation property Y were both A or B, the determination was acceptable, and other instances were determined to be failed.
A: The maximum temperature is lower than 25° C.
B: The maximum temperature is 25° C. or higher and lower than 30° C.
C: The maximum temperature is 30° C. or higher.

### (2) Lightness of Laminate 20

A sample having a width of 100 mm and a length of 100 mm (thickness is the thickness of the laminate 20) was cut out from the laminate 20, and the specific gravity was determined from the mass W and the apparent volume V of the sample by the following formula.

Specific gravity=W/V

When the value of the specific gravity was smaller than that of magnesium (AZ91, specific gravity: 1.82) as a metal material, the determination was acceptable, and the other instances were determined to be failed.

### Material Composition Example 1-1 Unidirectional Prepreg (C-1) 21

As a pitch-based prepreg, a unidirectional prepreg (C-1) 21 (a prepreg made of a resin and a pitch-based continuous carbon fiber manufactured by Nippon Graphite Fiber Corporation “GRANOC prepreg” (registered trademark), E8026A-07S, thermal conductivity in fiber direction: 320 W/(m·K), tensile modulus: 785 GPa, fiber density: 2.17 g/m³) was used.

### Material Composition Example 1-2 Unidirectional Prepreg (C-2) 21

As a PAN-based prepreg, a unidirectional prepreg (C-2) 21 (a prepreg made of a resin and a PAN-based continuous carbon fiber manufactured by Toray Industries, Inc. “TORAYCA (registered trademark) prepreg”, product type P3252S-10, thermal conductivity in the fiber direction: 5 W/(m· K), tensile modulus: 230 GPa, fiber density: 1.8 g/m³) was used.

### Material Composition Example 2 Foamed Molded Body 40

A non-cross-linked polypropylene sheet with low foaming ratio “EFCELL” (registered trademark) (double expansion) (manufactured by Furukawa Electric Co., Ltd.) was used.

### Material Composition Example 3 Chopped Carbon Fiber Bundle

PAN-based carbon fibers (“TORAYCA (registered trademark) yarn” manufactured by Toray Industries, Inc., product type: T700SC, thermal conductivity in fiber direction: 10 W/(m·K)) were cut with a cartridge cutter to obtain chopped carbon fiber bundles having a fiber length of 6 mm.

### Material Composition Example 4 Carbon Fiber Mat

A 1.5 wt % aqueous solution (100 liters) of a surfactant (“sodium n-dodecylbenzenesulfonate” (product name) manufactured by Wako Pure Chemical Industries, Ltd.) was stirred to prepare a pre-bubbled dispersion. The chopped carbon fiber bundles obtained in Material Composition Example 3 were put into the dispersion and stirred. The resulting mixture was poured into a paper machine having a paper surface having a length of 400 mm and a width of 400 mm, dehydrated by suction, and then dried at 150° C. for 2 hours to obtain a carbon fiber mat. The obtained mat was in a good dispersion state.

### Material Composition Example 5 Polypropylene Resin Film

Dry blending was performed using 90% by mass of an unmodified polypropylene resin (“Prime Polypro” (registered trademark) J105G manufactured by Prime Polymer Co., Ltd., melting point: 160° C.) and 10% by mass of an acid-modified polypropylene resin (“ADMER” (registered trademark) QE510 manufactured by Mitsui Chemicals, Inc., melting point: 160° C.), and a polypropylene resin film was obtained using the dry blend resin.

### Material Composition Example 6 Porous Substrate 50

Material Composition Example 4 and Material Composition Example 5 were used for lamination in the order of “polypropylene resin film/carbon fiber mat/polypropylene resin film”.

### Material Composition Example 7 Glass Fiber-Reinforced Polycarbonate

Glass fiber-reinforced polycarbonate compound pellets (“Panlite” (registered trademark) GXV-3545WI (manufactured by Teijin Chemicals Ltd.)) were used.

### Material Composition Example 8 Thermoplastic Resin Substrate 70

A polyester-based elastomer resin (“Hytrel” (registered trademark) manufactured by Du Pont-Toray Co., Ltd.) was used to obtain a polyester resin film having a thickness of 0.05 mm. The obtained film was used as the thermoplastic resin substrate 70.

### Example 1

In production of the integrally molded body 10 as illustrated in FIG. 1, the unidirectional prepreg (C-1) 21 prepared in Material Composition Example 1-1, the foamed molded body 40 prepared in Material Composition Example 2, and the thermoplastic resin substrate 70 prepared in Material Composition Example 8 were each adjusted to 400 mm by 400 mm, laminated in the order of “unidirectional prepreg (C-1) 21 0°/unidirectional prepreg (C-1) 21 90°/foamed molded body 40/unidirectional prepreg (C-1) 21 90°/unidirectional prepreg (C-1) 21 0°/thermoplastic resin substrate 70”, and press-molded in a flat mold heated to 150° C. under the condition of 3 MPa for 5 minutes to obtain a laminate 20.

Subsequently, the obtained laminate 20 was processed into 300 mm by 200 mm, then set in an injection mold, and the glass fiber-reinforced polycarbonate of Material Composition Example 7 was injected and molded at 150 MPa, a cylinder temperature of 320° C., a mold temperature of 120° C., and a resin discharge port of Φ 3 mm to form a structure 30, and an integrally molded body 10 illustrated in FIG. 1 was produced. The heat dissipation property of the obtained integrally molded body 10 was measured by the above-described method. The heat dissipation property X and the heat dissipation property Y both had a good result and were acceptable with the determination of A. The characteristics of the integrally molded body 10 are collectively shown in Table 1.

### Example 2

The unidirectional prepreg (C-1) 21 prepared in Material Composition Example 1-1, the porous substrate 50 prepared in Material Composition Example 6, and the thermoplastic resin substrate 70 prepared in Material Composition Example 8 were each adjusted to 400 mm by 400 mm, laminated in the order of “unidirectional prepreg (C-1) 21 0°/unidirectional prepreg (C-1) 21 90°/porous substrate 50/unidirectional prepreg (C-1) 21 90°/unidirectional prepreg (C-1) 21 0°/thermoplastic resin substrate 70”, and press-molded in a flat mold heated to 180° C. under the condition of 3 MPa for 5 minutes, and then 3 MPa for 3 minutes in a state where the mold interval was increased to 1.15 mm, and the porous substrate 50 was expanded in the thickness direction by spring back to form voids. Thereafter, press molding was performed under the condition of 3 MPa for 3 minutes with a mold having a step shape at a board surface temperature of 120° C., and the laminate 20 was cooled to form a step shape. With this procedure, regarding the porosity of the porous substrate, the porosity of the portion corresponding to the porous substrate region 50b as the inclined portion was lower than that of the portion corresponding to the porous substrate region 50a as the first flat portion in FIG. 6, and the porosity of the portion corresponding to the porous substrate region 50c as the second flat portion was further lower.

Injection molding was performed on the obtained laminate 20 under the same conditions as in Example 1 to obtain an integrally molded body 10, and the heat dissipation property thereof was measured by the above-described method. The heat dissipation property X and the heat dissipation property Y both had a good result and were acceptable with the determination of A. The characteristics of the integrally molded body 10 are collectively shown in Table 1.

### Example 3

The unidirectional prepreg (C-1) 21 prepared in Material Composition Example 1-1, the unidirectional prepreg (C-2) 21 prepared in Material Composition Example 1-2, and the thermoplastic resin substrate 70 prepared in Material Composition Example 8 were each adjusted to 400 mm by 400 mm, laminated in the order of “unidirectional prepreg (C-1) 21 0°/unidirectional prepreg (C-2) 21 90°/unidirectional prepreg (C-2) 21 0°/unidirectional prepreg (C-2) 21 90°/unidirectional prepreg (C-1) 21 0°/thermoplastic resin substrate 70”, and press-molded in a flat mold heated to 150° C. under the condition of 3 MPa for 5 minutes to obtain a laminate 20.

Subsequently, the obtained laminate 20 was processed into 300 mm by 200 mm, then set in an injection mold under the same conditions as in Example 1 to obtain an integrally molded body 10, and the heat dissipation property thereof was measured by the above-described method. The heat dissipation property X and the heat dissipation property Y both had a good result and were acceptable with the determination of A. The characteristics of the integrally molded body 10 are collectively shown in Table 1.

### Example 4

The unidirectional prepreg (C-1) 21 prepared in Material Composition Example 1-1 and the thermoplastic resin substrate 70 prepared in Material Composition Example 8 were each adjusted to 400 mm by 400 mm, laminated in the order of “unidirectional prepreg (C-1) 21 0°/unidirectional prepreg (C-1) 21 90°/unidirectional prepreg (C-1) 21 0°/unidirectional prepreg (C-1) 21 90°/unidirectional prepreg (C-1) 21 0°/thermoplastic resin substrate 70”, and press-molded in a flat mold heated to 150° C. under the condition of 3 MPa for 5 minutes to obtain a laminate 20.

Injection molding was performed on the obtained laminate 20 under the same conditions as in Example 1 to obtain an integrally molded body 10, and the heat dissipation property thereof was measured by the above-described method. The heat dissipation property X and the heat dissipation property Y both had a good result and were acceptable with the determination of B. The characteristics of the integrally molded body 10 are collectively shown in Table 1.

### Comparative Example 1

The unidirectional prepreg (C-2) 21 prepared in Material Composition Example 1-2 and the thermoplastic resin substrate 70 prepared in Material Composition Example 8 were each adjusted to 400 mm by 400 mm, laminated in the order of “unidirectional prepreg (C-2) 21 0°/unidirectional prepreg (C-2) 21 90°/unidirectional prepreg (C-2) 21 0°/unidirectional prepreg (C-2) 21 90°/unidirectional prepreg (C-2) 21 0°/thermoplastic resin substrate 70”, and press-molded in a flat mold heated to 150° C. under the condition of 3 MPa for 5 minutes to obtain a laminate 20.

Injection molding was performed on the obtained laminate 20 under the same conditions as in Example 1 to obtain an integrally molded body 10, and the heat dissipation property thereof was measured by the above-described method. The heat dissipation property X was determined to be C and the heat dissipation property Y was determined to be B, and the total result was determined to be failed. The characteristics of the integrally molded body 10 are collectively shown in Table 1.

### Comparative Example 2

The unidirectional prepreg (C-2) 21 prepared in Material Composition Example 1-2, the foamed molded body 40 prepared in Material Composition Example 2, and the thermoplastic resin substrate 70 prepared in Material Composition Example 8 were each adjusted to 400 mm by 400 mm, laminated in the order of “unidirectional prepreg (C-2) 21 0°/unidirectional prepreg (C-2) 21 90°/foamed molded body 40/unidirectional prepreg (C-2) 21 90°/unidirectional prepreg (C-2) 21 0°/thermoplastic resin substrate 70”, and press-molded in a flat mold heated to 150° C. under the condition of 3 MPa for 5 minutes to obtain a laminate 20.

Injection molding was performed on the obtained laminate 20 under the same conditions as in Example 1 to obtain an integrally molded body 10, and the heat dissipation property thereof was measured by the above-described method. The heat dissipation property X was determined to be failed and the heat dissipation property Y was determined to be B, and the total result was determined to be failed. The characteristics of the integrally molded body 10 are collectively shown in Table 1.

### Comparative Example 3

The unidirectional prepreg (C-1) 21 prepared in Material Composition Example 1-1, the unidirectional prepreg (C-2) 21 prepared in Material Composition Example 1-2, and the thermoplastic resin substrate 70 prepared in Material Composition Example 8 were each adjusted to 400 mm by 400 mm, laminated in the order of “unidirectional prepreg (C-2) 21 0°/unidirectional prepreg (C-1) 21 90°/unidirectional prepreg (C-1) 21 0°/unidirectional prepreg (C-1) 21 90°/unidirectional prepreg (C-2) 21 0°/thermoplastic resin substrate 70”, and press-molded in a flat mold heated to 150° C. under the condition of 3 MPa for 5 minutes to obtain a laminate 20.

Injection molding was performed on the obtained laminate 20 under the same conditions as in Example 1 to obtain an integrally molded body 10, and the heat dissipation property thereof was measured by the above-described method. The heat dissipation property X was determined to be failed and the heat dissipation property Y was determined to be B, and the total result was determined to be failed. The characteristics of the integrally molded body 10 are collectively shown in Table 1.

TABLE 1-1

| Integrally molded body | | Example 1 | Example 2 | Example 3 | Example 4 |
|---|---|---|---|---|---|
| Substrate | Substrate | Material | Material | Material | Material |
| configuration | (design surface | Composition | Composition | Composition | Composition |
| | side) | Example 1-1 | Example 1-1 | Example 1-1 | Example 1-1 |
| | Substrate | Material | Material | Material | Material |
| | | Composition | Composition | Composition | Composition |
| | | Example 1-1 | Example 1-1 | Example 1-2 | Example 1-1 |
| | Substrate | Material | Material | Material | Material |
| | | Composition | Composition | Composition | Composition |
| | | Example 2 | Example 6 | Example 1-2 | Example 1-1 |
| | Substrate | Material | Material | Material | Material |
| | | Composition | Composition | Composition | Composition |
| | | Example 1-1 | Example 1-1 | Example 1-2 | Example 1-1 |
| | Substrate | Material | Material | Material | Material |
| | | Composition | Composition | Composition | Composition |
| | | Example 1-1 | Example 1-1 | Example 1-1 | Example 1-1 |
| | Substrate (non- | Material | Material | Material | Material |
| | design surface | Composition | Composition | Composition | Composition |
| | side) | Example 8 | Example 8 | Example 8 | Example 8 |
| Lightness | Specific gravity | 0.77 | 0.72 | 1.63 | 1.74 |
| | Determination | Acceptable | Acceptable | Acceptable | Acceptable |
| | (lightness) | | | | |
| Thermal | λ1A | 320 | 320 | 320 | 320 |
| conductivity | λ2 (λ21, λ22, λ | 0.5 | 10 | 5 | 320 |
| [W/m · K] | 1B) | | | | |

| | | | | |
|---|---|---|---|---|
| λ2/λ1A | 0.002 | 0.031 | 0.016 | 1.000 |
| Heat dissipation property X | A | A | A | B |
| Heat dissipation property Y | A | A | A | B |
| Determination (heat | Acceptable | Acceptable | Acceptable | Acceptable |
| dissipation property) | | | | |

TABLE 1-2

| | | Comparative | Comparative | Comparative |
|---|---|---|---|---|
| Integrally molded body | | Example 1 | Example 2 | Example 3 |
| Substrate | Substrate | Material | Material | Material |
| configuration | (design surface | Composition | Composition | Composition |
| | side) | Example 1-2 | Example 1-2 | Example 1-2 |
| | Substrate | Material | Material | Material |
| | | Composition | Composition | Composition |
| | | Example 1-2 | Example 1-2 | Example 1-1 |
| | Substrate | Material | Material | Material |
| | | Composition | Composition | Composition |
| | | Example 1-2 | Example 2 | Example 1-1 |
| | Substrate | Material | Material | Material |
| | | Composition | Composition | Composition |
| | | Example 1-2 | Example 1-2 | Example 1-1 |
| | Substrate | Material | Material | Material |
| | | Composition | Composition | Composition |
| | | Example 1-2 | Example 1-2 | Example 1-2 |
| | Substrate (non- | Material | Material | Material |
| | design surface | Composition | Composition | Composition |
| | side) | Example 8 | Example 8 | Example 8 |
| Lightness | Specific gravity | 1.57 | 0.78 | 1.66 |
| | Determination | Acceptable | Acceptable | Acceptable |
| | (lightness) | | | |
| Thermal | λ1A | 5 | 5 | 5 |
| conductivity | λ2 (λ21, λ22, | 5 | 0.5 | 320 |
| [W/m · K] | λ 1B) | | | |

| | | | |
|---|---|---|---|
| λ2/λ1A | 1.000 | 0.100 | 64 |
| Heat dissipation property X | C | C | C |
| Heat dissipation property Y | B | B | B |
| Determination (heat | Failed | Failed | Failed |
| dissipation property) | | | |

### INDUSTRIAL APPLICABILITY

Our integrally molded body 10 can be effectively used in interiors and exteriors of motor vehicles, electric and electronic device housings, bicycles, structural materials for sports goods, aircraft interior materials, transportation boxes and the like.

1.-9. (canceled)

10. An integrally molded body comprising a laminate and a structure, the laminate including at least prepregs that are laminated and made of a continuous carbon fiber and a resin, the structure being made of a thermoplastic resin and a reinforcing fiber and disposed on a periphery of the laminate,
wherein the prepregs include a first prepreg constituting an outermost layer of the laminate and including a continuous carbon fiber having a thermal conductivity λ1A of 100 (W/(m·K)) or more and 800 (W/(m·K)) or less in a fiber direction.

11. The integrally molded body according to claim 10, wherein the laminate includes a core layer and the prepregs and has a sandwich structure with the prepregs being disposed on both sides of the core layer.

12. The integrally molded body according to claim 11, wherein the core layer is a foamed molded body made of a foamed resin, or a porous substrate made of a discontinuous fiber and a thermoplastic resin.

13. The integrally molded body according to claim 10 satisfying (i) and/or (ii) below:
(i) the laminate includes a core layer and the prepregs and has a sandwich structure with the prepregs being disposed on both sides of the core layer, and satisfies (i-1) or (i-2) below,
(i-1) the core layer is a foamed molded body made of a foamed resin, the foamed molded body having a thermal conductivity λ21, in which a ratio λ21/λ1A of the thermal conductivity λ21 to the thermal conductivity λ1A is more than 0 and 0.05 or less,
(i-2) the core layer is a porous substrate including a discontinuous fiber and a thermoplastic resin, the discontinuous fiber included in the porous substrate being a carbon fiber and having a thermal conductivity λ22 in a fiber direction, in which a ratio λ22/λ1A of the thermal conductivity λ22 to the thermal conductivity λ1A is more than 0 and 1.0 or less, and
(ii) the prepregs included in the laminate includes a dissimilar carbon fiber prepreg that is a prepreg other than the first prepreg and includes a continuous carbon fiber that is different in type from the continuous carbon fiber included in the first prepreg, in which a ratio λ1B/λ1A of a thermal conductivity λ1B of a carbon fiber having a lowest thermal conductivity in the dissimilar carbon fiber prepreg to the thermal conductivity λ1A is more than 0 and 1.0 or less.

14. The integrally molded body according to claim 10, wherein a density of the continuous carbon fiber included in the first prepreg is 2.0 g/cm³ to 2.5 g/cm³.

15. The integrally molded body according to claim 10, wherein a continuous fiber fabric substrate is disposed on a further outer side of at least one of outermost layers of the laminate to form a design surface.

16. The integrally molded body according to claim 10, wherein a thermoplastic resin substrate is at least partially disposed between the laminate and the structure.

17. The integrally molded body according to claim 10 that is used as an electronic device housing.

18. An electronic device housing including the integrally molded body according to claim 10.
